(19) United States
(12) Patent Application Publication
(10) Pub. No.: US 2009/0250754 A1
(43) Pub. Date: Oct. 8, 2009

(54) PARTIALLY DEPLETED SILICON-ON-INSULATOR METAL OXIDE SEMICONDUCTOR DEVICE

(75) Inventors: Yu-Hsin Lin, Hsinchu City (TW); Rai-Min Huang, Taipei City (TW); En-Chiuan Liou, Tainan County (TW); Chih-Wei Yang, Kaohsiung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 12/061,168

(22) Filed: Apr. 2, 2008

(51) Int. Cl. H01L 27/12; H01L 21/00

(52) U.S. Cl. 257/347; 438/151; 257/E27.112

(57) ABSTRACT

A partially depleted silicon-on-insulator metal oxide semiconductor (PD-SOI MOS) device is provided. The PD-SOI MOS device includes a gate structure on a silicon-on-insulator substrate, source and drain regions in the silicon-on-insulator substrate beside the gate structure and a silicon dislocation leakage path in an interface of the source region and the silicon-on-insulator substrate.

### BACKGROUND OF THE INVENTION

1. Field of Invention

The present invention relates to a metal oxide semiconductor device and a method of fabricating the same. More particularly, the present invention relates to a partially depleted silicon-on-insulator metal oxide semiconductor device and a method of fabricating the same.

2. Description of Related Art

A silicon-on-insulator substrate is a type of substrate in which a silicon insulation layer is grown on a conventional silicon wafer, followed by growing a silicon body to sandwich the oxide layer in between the two silicon layers. The research conducted in the industry indicates that under the same controlled conditions, the conduction speed of a SOI wafer is about 20% to 30% faster than that of a conventional bulk silicon wafer, and a device formed with a SOI wafer is superior in preserving electrical energy. Additionally, when a silicon film layer becomes thinner, a smaller bias voltage is required to be applied to the gate to generate an inversion layer to lower the limit voltage. Hence, the threshold voltage of a SOI device can be reduced and the fabrication method thereof is simpler than that of a traditional MOS device. Therefore, the application of SOI devices have been actively pursued due to the recent demands, such as a small device dimension, low power consumption, low leakage and high operating speed, in the industry.

In a semiconductor memory device, using the body effect of a partially depleted silicon-on-insulator metal oxide semiconductor transistor (PD-SOI MOSFET) to form a single transistor memory device greatly reduces the area of the memory device. However, there are problems with the partially depleted silicon-on-insulator metal oxide semiconductor transistor. The charges generated in the drain depletion region of a PD-SOI MOSFET or the charges generated by high electric field impact ionization effect are accumulated in the body of a SOI substrate. The accumulation of a large amount of charges causes the electrical potential of the SOI substrate to increase. Hence, during the early period of the operation, the threshold voltage greatly decreases due to the significant increase of the substrate electrical potential. Only after a certain period of operation, the threshold voltage of the device is lowered to the pre-determined value. This phenomenon is known as the history effect, which seriously affect the stability of a partially depleted silicon-on-insulator metal oxide semiconductor transistor.

### SUMMARY OF THE INVENTION

The present invention is to provide a partially depleted silicon-on-insulator metal oxide semiconductor device, in which the charges generated in the body during the operation of the device can be eliminated. Hence, the changes in the threshold voltage resulted from the history effect is minimized and the threshold voltage may readily reach a stable value.

The present invention is to provide a method for fabricating a partially depleted silicon-on-insulator metal oxide semiconductor device, in which the lowering of the history effect can be achieved by a simple fabrication process.

The present invention is to provide a partially depleted silicon-on-insulator metal oxide semiconductor device, which includes a gate structure, a source region, a drain region and a silicon dislocation leakage path. The gate structure, including a gate and a gate dielectric layer, is configured on the silicon-on-insulator (SOI) substrate. The source region and the drain region are configured in the SOI substrate beside two sides of the gate structure. The silicon dislocation leakage path is configured at an interface between the source region and the SOI substrate.

In accordance to an embodiment of the present invention, in the above partially depleted silicon-on-insulator metal oxide semiconductor device, the above silicon dislocation leakage path is configured at an interface between the above source region and the body layer of the above SOI substrate.

In accordance to an embodiment of the present invention, in the above partially depleted silicon-on-insulator metal oxide semiconductor device, the above-mentioned source region and drain region are respectively include a contact region and an extension region. Moreover, the above-mentioned silicon dislocation leakage path is configured at an interface between the contact region of the source region and the above-mentioned SOI substrate.

In accordance to an embodiment of the present invention, in the above partially depleted silicon-on-insulator metal oxide semiconductor device, the above-mentioned silicon dislocation current leakage path contains hydrogen atoms or nitrogen atoms or a combination thereof.

In accordance to an embodiment of the present invention, in the above partially depleted silicon-on-insulator metal oxide semiconductor device, the content of the hydrogen atoms in the above-mentioned silicon dislocation leakage path is higher than that at the near-by source region or the near-by SOI substrate.

In accordance to an embodiment of the present invention, in the above partially depleted silicon-on-insulator metal oxide semiconductor device, the above-mentioned source region and the above mentioned drain region are respectively N-type doped regions or P-type doped regions.

In accordance to an embodiment of the present invention, in the above partially depleted silicon-on-insulator metal oxide semiconductor device, the partially depleted silicon-on-insulator metal oxide semiconductor device does not include a body contact.

The present invention provides a method for fabricating a partially depleted silicon-on-insulator metal oxide semiconductor device. The method includes forming a gate structure, and the gate structure includes a gate and a gate dielectric layer. A source region and a drain region are formed in the above-mentioned SOI substrate beside two sides of the gate structure. A silicon dislocation leakage path is formed at an interface between the above-mentioned source region and the above-mentioned SOI substrate.

In accordance to an embodiment of the present invention, in the above fabrication method of a partially depleted silicon-on-insulator metal oxide semiconductor device, forming the above-mentioned silicon dislocation current leakage path includes performing a first ion implantation process.

In accordance to an embodiment of the present invention, in the above fabrication method of a partially depleted silicon-on-insulator metal oxide semiconductor device, the ions implanted in the first ion implantation process include hydrogen.

In accordance to an embodiment of the present invention, in the above fabrication method of a partially depleted silicon-on-insulator metal oxide semiconductor device, the energy being used in performing the first ion implantation process is abut 5 to 10 KeV.

In accordance to an embodiment of the present invention, in the above fabrication method of a partially depleted silicon-on-insulator metal oxide semiconductor device, the implanted dosage of the first ion implantation process is about 1×10¹⁴/cm² to 5×10⁴/cm².

In accordance to an embodiment of the present invention, in the above fabrication method of a partially depleted silicon-on-insulator metal oxide semiconductor device, forming the above-mentioned source region and drain region includes sequentially performing a second ion implantation process and an anneal process. The above-mentioned first ion implantation process is performed prior to the above-mentioned anneal process.

In accordance to an embodiment of the present invention, in the above fabrication method of a partially depleted silicon-on-insulator metal oxide semiconductor device, the above-mentioned second ion implantation process includes an ion implantation process for forming the extension region and an ion implantation process for forming the contact region.

In accordance to an embodiment of the present invention, in the above fabrication method of a partially depleted silicon-on-insulator metal oxide semiconductor device, the mask used in the first ion implantation process is the same mask being used in the ion implantation process for forming the extension region.

In accordance to an embodiment of the present invention, in the above fabrication method of a partially depleted silicon-on-insulator metal oxide semiconductor device, the mask being used in the first ion implantation process is different from the mask being used in the ion implantation process for forming the extension region.

In accordance to an embodiment of the present invention, in the above fabrication method of a partially depleted silicon-on-insulator metal oxide semiconductor device, the mask being used in the first ion implantation process is a mask that has an opening, and the opening corresponds to a region designated for forming the above-mentioned silicon dislocation leakage path in the SOI substrate.

In accordance to an embodiment of the present invention, in the above fabrication method of a partially depleted silicon-on-insulator metal oxide semiconductor device, the above-mentioned first ion implantation process can be performed between any two steps prior to the above-mentioned anneal process.

In accordance to the embodiments of the invention, by forming a silicon dislocation leakage path in the partially depleted silicon-on-insulator metal oxide semiconductor device, the threshold voltage of the device readily reaches a steady value.

In accordance to the simple fabrication process of the present invention, the history effect is lowered by only incorporating a single step of forming a silicon dislocation leakage path.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A and 1B are schematic views of a partially depleted silicon-on-insulator metal oxide semiconductor device according to an embodiment of the present invention.

FIGS. 2A to 2D are schematic, cross-sectional views showing selected steps for the fabrication of a partially depleted silicon-on-insulator metal oxide semiconductor device according to an embodiment of the present invention.

FIG. 2 is a flow diagram corresponding to the selected process steps in FIGS. 2A to 2D.

FIGS. 3A to 3B are schematic, cross-sectional views showing selected steps for the fabrication of a partially depleted silicon-on-insulator metal oxide semiconductor device according to an embodiment of the present invention.

FIG. 3 is a flow diagram corresponding to the selected process steps in FIGS. 3A to 3B.

### DESCRIPTION OF EMBODIMENTS

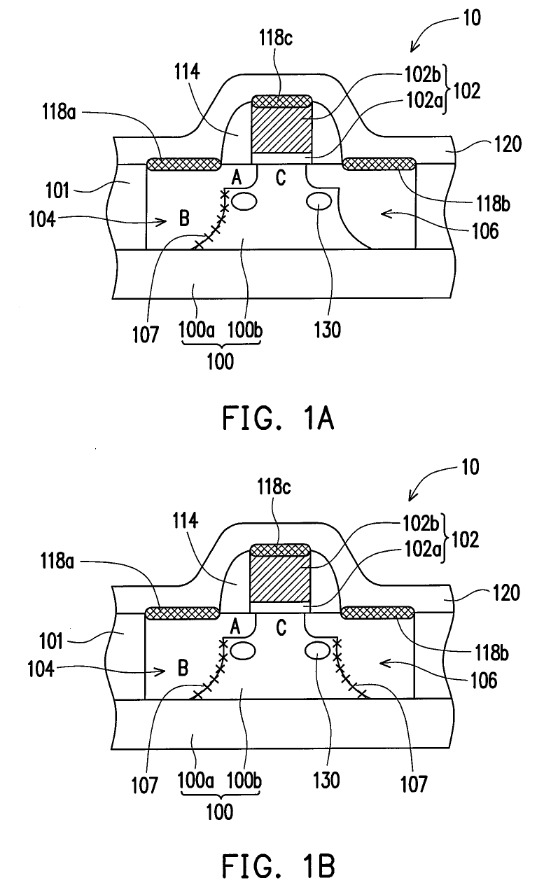

FIGS. 1A and 1B are schematic views of a partially depleted silicon-on-insulator metal oxide semiconductor device according to an embodiment of the present invention.

Referring to FIGS. 1A and 1B, a partially depleted silicon-on-insulator metal oxide semiconductor (PD-SOI MOS) device 10 includes a SOI substrate 100, a gate structure 102, a source region 104 and a drain region 106, and a silicon dislocation leakage path 107. A SOI substrate 100 is a general term referring to a bottom layer (not shown), a buried oxide (BOX) layer 100a and a body layer 100b. The BOX layer 100a may include silicon oxide or other insulation material. The body layer may be a silicon layer, but the body layer 100b is not limited to a silicon layer. Other semiconductor layer or semiconductor compound layer may also be used as the body layer 10b. The PD-SOI MOS device 10 does not include a body contact.

The gate structure 102 is positioned on the body layer 100b of the SOI substrate 100, wherein the gate structure 102 includes a gate 102b and a gate dielectric layer 102a. The gate 102b may include a doped polysilicon layer, or a doped polysilicon layer and a metal silicide layer 118c composed together. The gate dielectric layer 102a is configured between the gate 102b and the body layer 100b of the SOI substrate 100. A material of the gate dielectric layer 102a includes, for example, silicon oxide, silicon nitride, silicon oxynitride or a high dielectric constant material with a dielectric constant higher than 4.

The source region 104 and the drain region 106 are configured in the body layer 100b beside two sides of the gate structure 102. In one embodiment, the source region 104 and the drain region 106 are respectively include an extension region A and a contact region B. A channel region C is formed between the extension regions A of the source region and the drain region under the gate structure 102. The dopants used in the source region 104 and the drain region 106 are the same, which can be N type dopants or P type dopants.

The silicon dislocation leakage path 107 is configured only at the interface between the contact region B of the source region 104 and the body layer 100b, as shown in FIG. 1A or is configured concurrently at the interface between the contact region B of the source region 104 and the body layer 100b and the interface between the contact region B of the drain region 106 and the body layer 100b, as shown in FIG. 1B. In one embodiment, the silicon dislocation leakage path 107 is generated from implanting hetero-atoms, such as hydrogen atoms, that are different from the dopants in the source region 104 and the drain region 106. Accordingly, the content of the hetero-atoms at the interface between the contact region B of the source region 104 and the body layer 100b is higher than the content of the hetero-atoms at the nearby contact region B of the source region 104 and is higher than the content of the hetero-atoms at the nearby body layer of the SOI substrate 100.

Asides from the SOI substrate 100, the gate structure 102, the source region 104 and the drain region 106, and the silicon dislocation leakage path 107, the PD-SOI MOS device 10 also includes a pocket type doped region 130 respectively underneath the extension region A of the source region 104 and the extension region A of the drain region 106. The dopant type of the pocket doped region 130 is different from the dopant type of the source region 104 and the drain region 106. When the dopant type of the source region 104 and the drain region 106 is an N-type, the dopant type of the pocket doped region is a P-type; when the dopant type of the source region 104 and the drain region 106 is a P-type, the dopant type of the pocket doped region is an N-type. Moreover, the source region 104 and the drain region 106 and the gate 102b may also include metal silicide layers 118a, 118b, 118c thereon. The SOI substrate 100 may also covered with a stress layer 120.

The following embodiments are used to illustrate the fabrication method of a partially depleted silicon-on-insulator metal oxide semiconductor (PD-SOI MOS) device of the present invention.

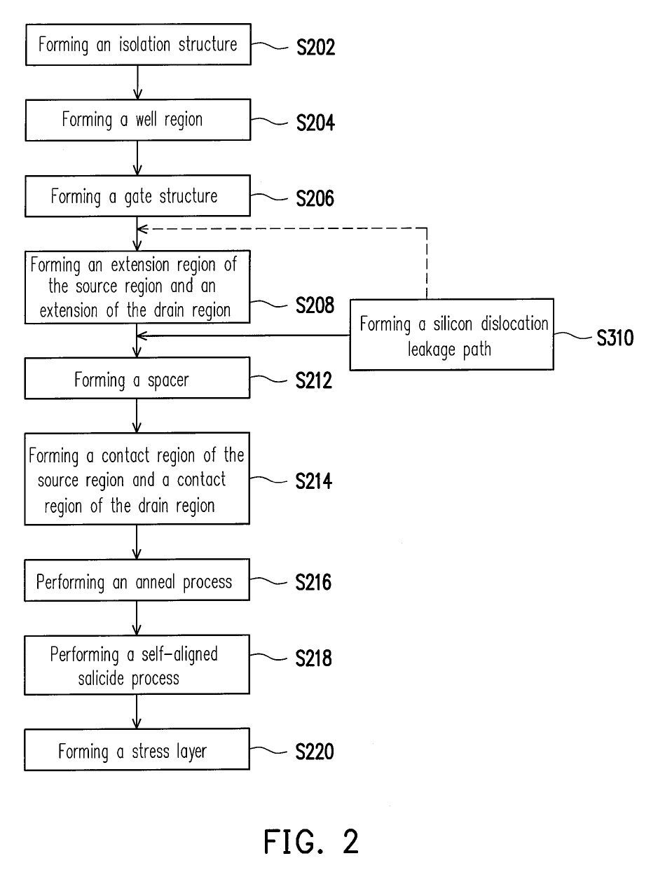

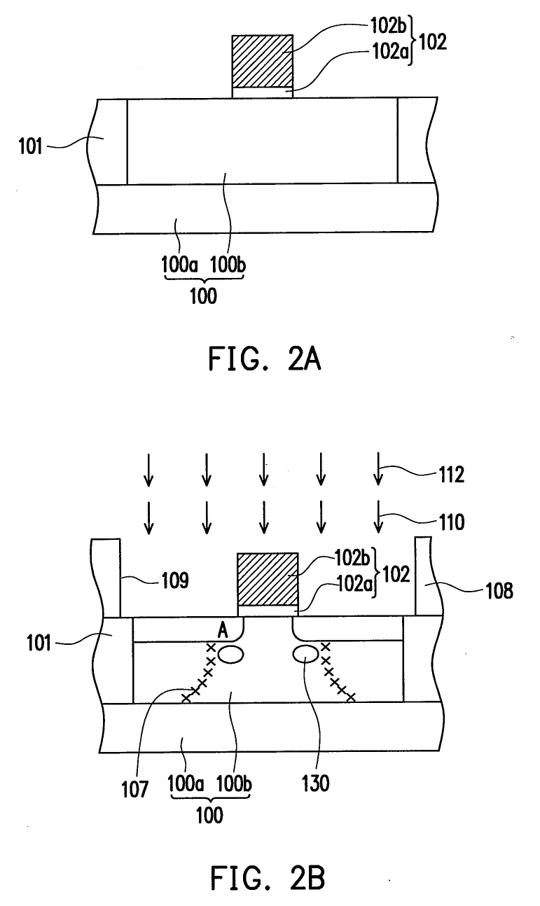

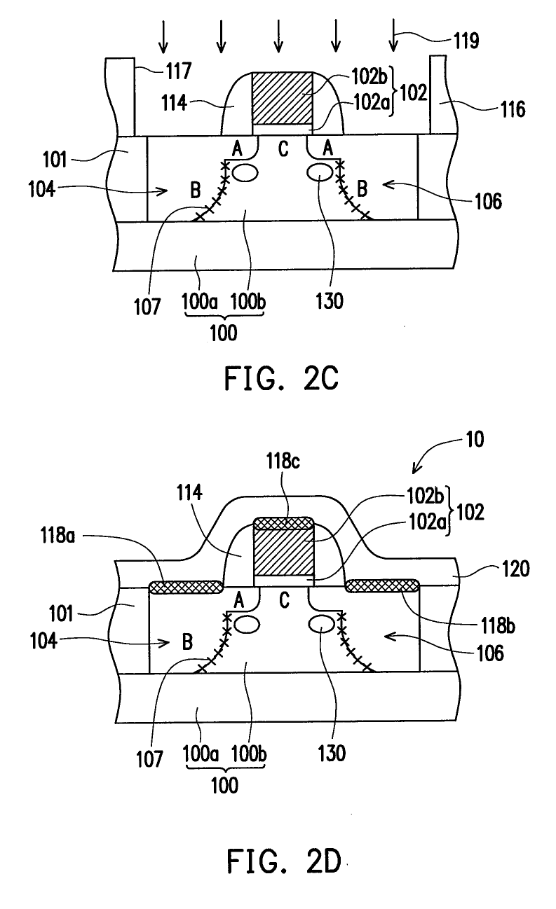

FIGS. 2A to 2D are schematic, cross-sectional views showing selected steps for the fabrication of a partially depleted silicon-on-insulator metal oxide semiconductor device according to an embodiment of the present invention. FIG. 2 is a flow diagram corresponding to the selected process steps in FIGS. 2A to 2D.

Referring to FIGS. 2 and 2A, providing a SOI substrate 100 that includes a BOX layer 100a and a body layer 100b. Isolation structures 101 are formed in the body layer 100b as in step S202. The isolation structures 101 are formed by shallow trench isolation method or local oxidation method. Thereafter, a well region (not shown) is formed in the body layer 100b, as shown in step S204. A gate structure 102 is further formed on the SOI substrate 100 as in step S206. The gate structure 102 includes, for example, a gate dielectric layer 102a and a gate 102b. The gate structure 102 is formed by, for example, sequentially forming a gate dielectric material layer (not shown) and a gate conductive material layer (not shown), followed by performing a patterning process. The material of the gate dielectric material layer includes, but not limited to, silicon oxide, silicon nitride, silicon oxynitride or a high dielectric constant material having a dielectric constant higher than 4. The gate conductive material layer includes a doped polysilicon layer or a doped polysilicon layer and a metal silicide layer composed together. The gate conductive material layer is formed by chemical vapor deposition, for example.

Thereafter, referring to FIG. 2 and FIG. 2B, an extension region A of the source region and an extension region A of the drain region are formed in the body layer 100b beside two sides of the gate structure 102, as in step S208. Forming the extension region A of the source region and the extension region A of the drain region includes forming a mask layer 108 over the SOI substrate 100. The mask layer 108 includes an opening 109 that exposes a region between the isolation structures 101. An ion implantation process 110 is then performed. When the partially depleted silicon-on-insulator metal oxide semiconductor (PD-SOI MOS) device is an N-type channel metal oxide semiconductor device, the dopants implanted in the ion implantation process 100 are N-type, such as, phosphorous or arsenic. On the other hand, when the partially depleted silicon-on-insulator metal oxide semiconductor (PD-SOI MOS) device is a P-type channel metal oxide semiconductor device, the dopants implanted in the ion implantation process 100 are P-type, such as, boron.

In one embodiment, step S310 in forming the silicon dislocation leakage path 107 of the invention may be conducted during the stage of forming the extension region A of the source region and the drain region. For example, the step S310 in forming the silicon dislocation leakage path 107 of the invention may be conducted after the mask is formed and after the ion implantation process for forming the extension region A using the mask or after the mask is formed and prior to the ion implantation process for forming the extension region A. The silicon dislocation leakage path 107 is formed by, for example, using the mask 108 to perform an ion implantation process to implant hetero-atoms, for example, hydrogen atoms or nitrogen atoms or a combination thereof, to the predetermined interface between the contact regions B of the source region and the drain region and the body layer to destroy to crystal lattices in the body layer 100b and to generate dislocation. Hence, a leakage path is formed during the operation of the device. In one embodiment, the implanted ions are hydrogen atoms, and the implantation energy in the ion implantation process of hydrogen atoms is about 5 to about 10 KeV, and the implanted dosage is about 1 to 5×10⁴/cm². The above implantation energy and dosage may vary according to the dimensions and electrical demands of a device. In another embodiment, the implanted ions are nitrogen atoms. At this stage of the fabrication process, a pocket doped region 130 may also form under the extension regions A of the source region 104 and the drain region 106. The dopant type of the pocket doped region 130 is different from the dopant type of the source region 104 and the drain region 106. When the dopant type of the source region 104 and the drain region 106 is N type, the dopant type of the pocket doped region 130 is P type; when the dopant type of the source region 104 and the drain region 106 is P type, the dopant type of the pocket doped region 130 is N type.

Thereafter, as shown in FIG. 2 and FIG. 2C, the mask layer 108 is removed. A spacer 114 is then formed on the sidewall of the gate structure 102, as in step S212. The material of the spacer 114 may be silicon oxide or silicon nitride, for example. Further, the spacer 114 may be a single layer spacer 114 or a double layer spacer 114. The extension regions B of the source region 104 and of the drain region 106 are formed in the body layer 100b beside two sides of the spacer 114, as in step S214, to complete the formation of the source region 104 and the drain region 106. Forming the extension region B of the source region 104 and the extension region B of the drain region 106 includes forming a mask layer 116 over the SOI substrate 100, wherein the mask layer 116 has an opening 117 that exposes a region between the isolation structures 101, followed by performing an ion implantation process 119. When the partially depleted silicon-on-insulator metal oxide semiconductor (PD-SOI MOS) device is an N-type channel metal oxide semiconductor device, the implanted ions are N-type ions, such as phosphorous or arsenic. On the other hand, when the partially depleted silicon-on-insulator metal oxide semiconductor (PD-SOI MOS) device is a P-type channel metal oxide semiconductor device, the dopants implanted in the ion implantation process 100 are P-type, such as, boron.

Continuing to FIG. 2 and FIG. 2D, the mask layer 116 is removed. Thereafter, an anneal process is performed, as in step S216. Relying on the temperature and the time period of the anneal process, the dopants in the source region 104 and the drain region 106 can be activated. However, the dislocation at the interface of the contact regions B of the source region 104 and the drain region 106 can not be repaired. In other words, after the anneal process, the dislocation leakage path is retained. In one embodiment, the anneal process, for example, a spike anneal process, is conducted at a temperature higher than 1000 degrees Celsius, and the preferred temperature is 1078 degrees Celsius for less than a second. Thereafter, a self-aligned salicide process is performed to form metal silicide layers 118a, 118b, 118c on the source region 104, the drain region 106 and the gate 102b as in step S218. The material of the metal silicide layers 118a, 118b, 118c include, for example, a refractory metal, such as, nickel, cobalt, titanium, copper, molybdenum, tantalum, tungsten, erbium, berkelium, platinum, or alloy of the above metals. A stress layer 120 is then formed on the SOI substrate 100 in step S220. The material of the stress layer includes, but not limited to, silicon nitride, formed chemical vapor deposition.

In the above embodiment, the step S310 of forming the silicon dislocation leakage path 107 is conducted during the stage of forming the extension regions A of the source region 104 and drain region 106. However, the step S310 of forming the silicon dislocation leakage path 107 may also be conducted at other stages.

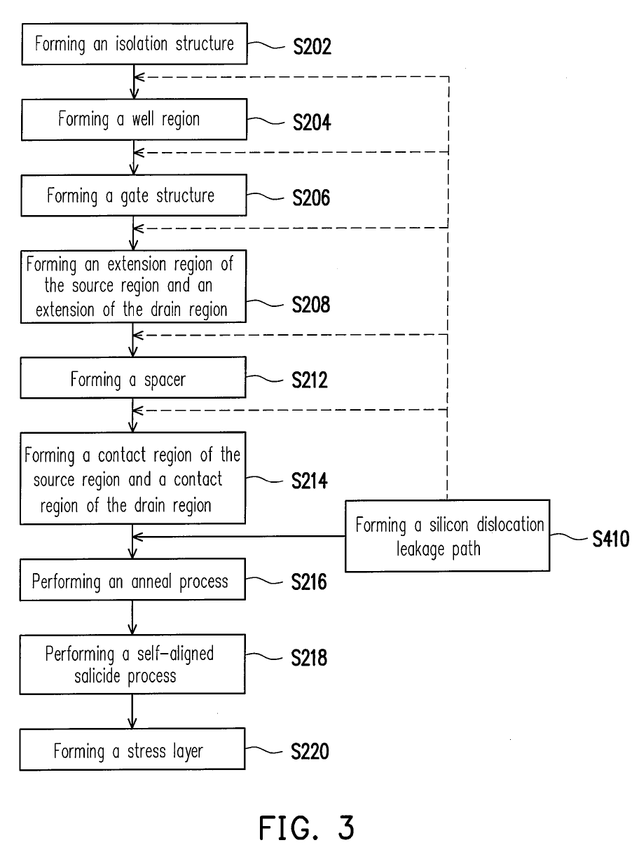

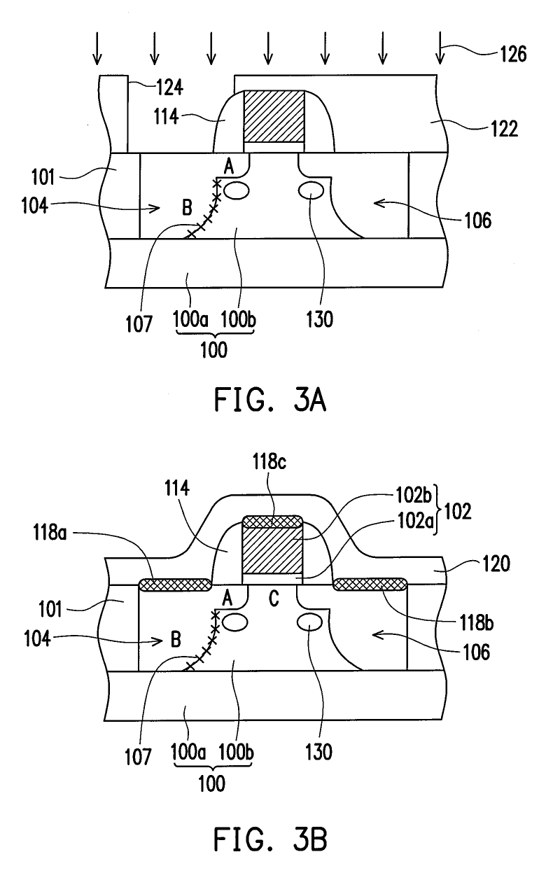

FIGS. 3A to 3B are schematic, cross-sectional views showing selected steps for the fabrication of a partially depleted silicon-on-insulator metal oxide semiconductor device according to an embodiment of the present invention. FIG. 3 is a flow diagram corresponding to the selected process steps in FIGS. 3A to 3B.

Referring to FIG. 3 and FIG. 3A, according to the above-mentioned steps S202 to S208, the step of forming the silicon dislocation leakage path is not conducted subsequent to forming the isolation structure 101, the gate structure 102, the extension regions B of the source region 104 and the drain region 106. Instead, steps S212 and S214 are directly performed to form the spacer 114 and the contact regions B of the source region 104 and the drain region 106, followed by performing step S410 of forming the silicon dislocation leakage path 107. The step S410 in forming the silicon dislocation leakage path 107 includes forming a mask layer 122 over the SOI substrate. The mask layer 122 is different from the mask layer used in forming the extension regions A of the source region 104 and the drain region 106. The mask layer 122 has an opening 124 that exposes a region corresponding to the interface between the contact region B of the source region 104 in the SOI substrate 100 and the body layer 100b. The mask layer 122 is then used to perform an ion implantation process 126 to implant hetero-atoms, such as hydrogen atoms or nitrogen atoms, to the interface at the contact region B of the source region to destroy the crystal lattices of the body layer 100b and to generate dislocation. A silicon dislocation leakage path 107 is then formed at the contact region B of the source region 104. In one embodiment, the implantation energy of the implantation process of the hydrogen atoms for forming the silicon dislocation leakage path is about 5 to about 10 KeV, and the implanted dosage is about 1×10⁴/cm² to 5×10¹⁴/cm².

Referring to FIGS. 3 and 3B, the mask layer 122 is removed. Then, steps S216 to S220 are conducted according the above embodiment.

In the above embodiment, the step S410 in forming the silicon dislocation leakage path 107 is performed after the step S214 in forming the contact regions B of the source region 104 and the drain region 106. However, the present invention is limited as such. For example, step S410 may be performed between any two steps that is before the step of the anneal process (S216) of the source region 104 and the drain region 106. Moreover, the sequence of each of the steps S202 to S214 prior to the anneal process step S216 is not limited to those disclosed in the above embodiments. For example, in the above embodiment, the sequence of performing the step S208 of forming the extension regions A of the source region 104 and the drain region 106, the step of forming the spacer 114 and the step S214 of forming the contact regions B of the source region 104 and the drain region 106 can be altered to performing the step S212 of forming the spacer 114 and the step S214 of forming the contact region B of the source region 104 and the drain region 106, followed by performing the step S208 of forming the extension regions A of the source region 104 and the drain region 106 and then forming another spacer.

In accordance to the embodiments of the present invention, by forming a silicon dislocation leakage path at the interface between the contact region of the source region in the partially depleted SOI-MOS device and the SOI substrate, the charges generated in the body layer during operations are conducted away to lower the changes in the threshold voltages resulted from the history effect. Hence, the threshold voltage readily achieves a stable value.

According to the embodiments of the present invention, the fabrication process of the present invention is simple. Lowering the history effect is achieved by only adding a single step of forming a silicon dislocation leakage path.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A partially depleted silicon-on-insulator metal oxide semiconductor (PD-DOI MOS) device comprising:
a gate structure, configured on a insulator-on-silicon substrate, wherein the gate structure comprises a gate and a gate dielectric layer, and the gate dielectric layer is positioned between the gate and the insulator-on-silicon substrate;
a source region and a drain region, positioned in the insulator-on-silicon substrate besides two sides of the gate structure; and
a silicon dislocation leakage current path, configured at a interface between the source region and the silicon-on-insulator (SOI) substrate.

2. The partially depleted silicon-on-insulator metal oxide semiconductor device of claim 1, wherein the silicon dislocation leakage current path is configured at the interface between the source region and a body layer of the SOI substrate.

3. The partially depleted silicon-on-insulator metal oxide semiconductor device of claim 1, wherein the silicon dislocation leakage current path is also configured a interface between the drain region and the SOI substrate.

4. The partially depleted silicon-on-insulator metal oxide semiconductor device of claim 1, wherein the source region and the drain region are respectively include a contact region and an extension region, and the silicon dislocation leakage current path is configured at the interface between the contact region of the source region and the SOI substrate.

5. The partially depleted silicon-on-insulator metal oxide semiconductor device of claim 1, wherein the silicon dislocation leakage path comprises hydrogen atoms or nitrogen atoms.

6. The partially depleted silicon-on-insulator metal oxide semiconductor device of claim 5, wherein the content of the hydrogen atoms in the silicon dislocation leakage path is higher than that in the nearby source region and the SOI substrate.

7. The partially depleted silicon-on-insulator metal oxide semiconductor device of claim 1, wherein the source region and the drain region are N-type doped regions.

8. The partially depleted silicon-on-insulator metal oxide semiconductor device of claim 1, wherein the source region and the drain region are P-type doped regions.

9. The partially depleted silicon-on-insulator metal oxide semiconductor device of claim 1, wherein the partially depleted silicon-on-insulator metal oxide semiconductor device does not include a body layer contact.

10. A method for fabricating a partially depleted silicon-on-insulator metal oxide semiconductor device, the method comprising:
forming a gate structure on a silicon-on-insulator (SOI) substrate, wherein the gate structure comprises a gate and a gate dielectric layer, and the gate dielectric layer is configured between the gate and the SOI substrate;
forming a source region and a drain region in the SOI substrate beside two sides of the gate structure; and
forming a silicon dislocation leakage path at a interface between the source region and the SOI substrate.

11. The method of claim 10, wherein the silicon leakage path is formed by performing a first ion implantation process.

12. The method of claim 11, wherein ions implanted during the first ion implantation process comprise hydrogen.

13. The method of claim 11, wherein energy of the first ion implantation process is about 5 to about 10 KeV.

14. The method of claim 11, wherein an implanted dosage of the first ion implantation process is about 1×10¹⁴/cm² to about 5×10¹⁴/cm².

15. The method of claim 11, wherein the source region and the drain region are formed by sequentially performing a second ion implantation process and an anneal process, wherein the first ion implantation process is conducted prior to the anneal process.

16. The method of claim 15, wherein the second ion implantation process comprises an ion implantation process for forming an extension region and an ion implantation process form forming a contact region.

17. The method of claim 16, wherein the first ion implantation process and the ion implantation process for forming the extension region use a same mask.

18. The method of claim 16, wherein a mask used in the first ion implantation process is different from a mask used in the ion implantation process for forming the extension region.

19. The method of claim 18, wherein the mask used in the first ion implantation process comprises a mask with an opening, wherein the opening corresponds to a region in the SOI substrate designated for forming the silicon dislocation leakage path.

20. The method of claim 18, wherein the first ion implantation is conducted between any two steps that are prior to the step of the anneal process.
